(19) United States
(12) Patent Application Publication
(10) Pub. No.: US 2017/0073826 A1
(43) Pub. Date: Mar. 16, 2017

(54) SOLAR-POWERED SINGLE-COMPARTMENT MULTI-PURPOSE ELECTROCHEMICAL REACTOR

(71) Applicants: ROYAL SCIENTIFIC SOCIETY, Amman (JO); SCIENTIFIC RESEARCH SUPPORT FUND MINISTRY OF HIGHER EDUCATION, Amman (JO)

(72) Inventor: Farqad Faeq MOHAMMED SAEED AL-HADEETHI, Amman (JO)

(21) Appl. No.: 14/852,651

(22) Filed: Sep. 14, 2015

(51) Int. Cl. C25B 15/02; H01L 31/042; C25B 9/06

(52) U.S. Cl. CPC C25B 15/02; C25B 9/06; H01L 31/042

(57) ABSTRACT

A solar-powered single-compartment multi-purpose electrochemical reactor; which can be used for the desalination of sea water, removal of heavy metals from drinking water, treatment of waste water, producing wide range of chemicals, producing hydrogen gas by electrolyzing water; which is useful as a source of energy. The device uses solar cells that convert solar energy into electrical energy in order to power such system. The device comprises: solar panels, car batteries to store the electrical energy obtained from such solar panels in order to power such device, a source tank for holding the electrolyte, a container for storing such electrolyte to be then fed to the electrolyzer, a pump, a flow meter, an electrolyzer; wherein such electrolyzer comprises an inlet section, a working section, and an outlet section; and such electrolyzer is a single-compartment electrolyzer. The device also comprises a plurality of valves and pipes, and a flash distillation tank.

### FIELD OF THE INVENTION

The field of the present invention relates to electrochemical reactors, particularly those that electrolyzes liquid electrolytes such as sea water using energy from solar panels, which are used for multi-purposes.

### BACKGROUND OF THE INVENTION

Electrolysis is a known process and can be used to extract metals and precious elements from their ores, or for desalination of sea water, or generating hydrogen gas as a source of energy.

New enhanced electrochemical devices and methods are needed which are simple, efficient and useful in solving the corrosion, blockage and separation problems in addition to the membrane related problems.

### SUMMARY OF THE INVENTION

The present invention provides a solar-powered single-compartment multi-purpose electrochemical reactor device that uses electrical energy obtained from solar cells to operate such device.

Said device comprises: solar cells, car batteries, a source tank for holding electrolyte, a container for storing such electrolyte to be then fed to an electrolyzer, a pump, a flow meter, an electrolyzer; wherein such electrolyzer comprises an inlet section, a working section, and an outlet section; and wherein such electrolyzer is made of corrosion resistant materials. The device of the present invention also comprises a plurality of valves and pipes, and a flash distillation unit.

Said device can for example electrolyze water into hydrogen and oxygen gases that are evolved as bubbles at the outlet section of said electrolyzer due to the presence of unelectrolyzed water in such electrolyzer.

To measure the production rate of any substance, the turbulent flow fundamental aspect of transport is used, since such fundamental aspect is convenient for obtaining transport rate correlations that are used to measure such production rate.

### BRIEF DESCRIPTION OF THE DRAWINGS

The invention will now be described with reference to the accompanying drawings, which illustrate a preferred embodiment of the present invention without restricting the scope of the invention, and in which:

FIG. 1 illustrates the layout of a solar-powered multi-purpose single-compartment electrochemical reactor designed according to a preferred embodiment of the present invention.

FIG. 2 illustrates an exploded view of the electrolyzer designed according to a preferred embodiment of the present invention.

### DETAILED DESCRIPTION OF THE PREFERRED EMBODIMENT

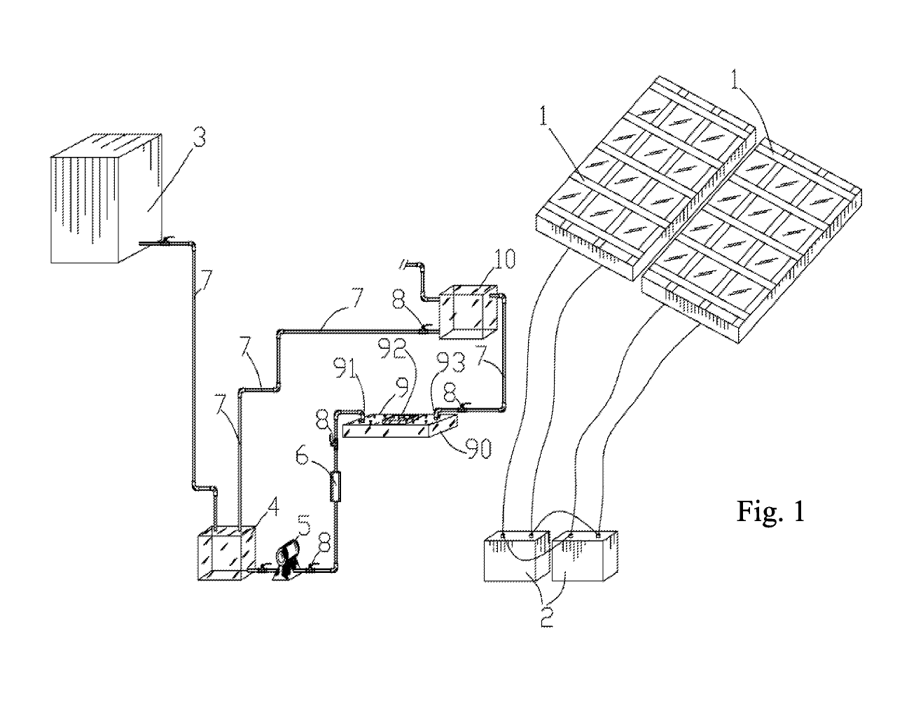

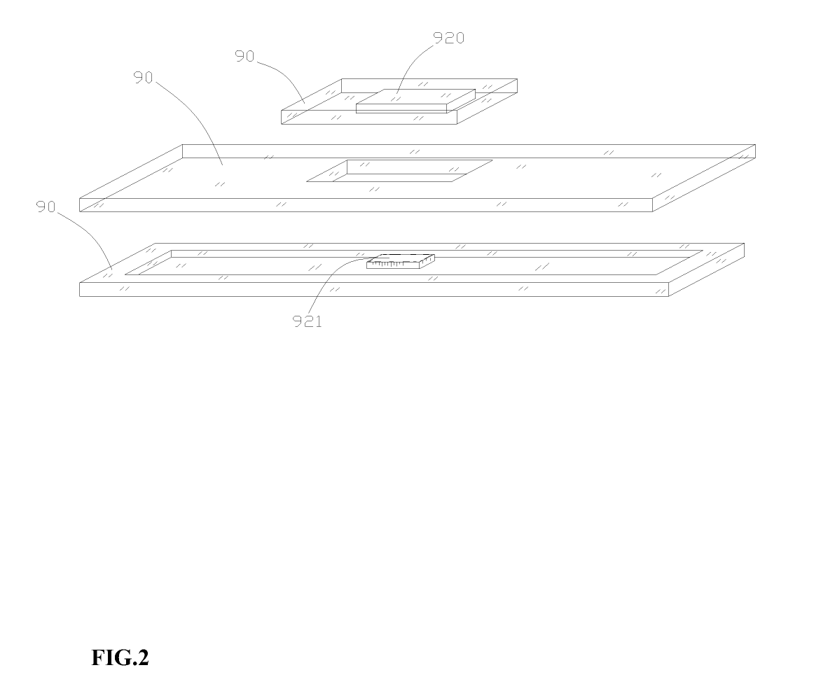

FIGS. 1 and 2 illustrate a solar powered single-compartment multi-purpose electrochemical reactor configured according a preferred embodiment of the present invention, such embodiment comprises: solar panels 1; wherein such panels are used to convert solar energy to electrical energy, a plurality of car batteries 2; wherein such batteries are used to store the converted energy that is obtained from said panels 1 such that this stored energy can power the device at night or at when said panels can't supply the desired amount of electrical energy; especially in the absence of solar light, a source tank 3; wherein such tank is used to hold the electrolyte, a container 4 to store such electrolyte to be then electrolyzed, a pump 5 for pumping such electrolyte from such container 4 throughout the system, a flow meter 6 to measure the flow rate of such electrolyte after its pumping process, plurality of pipes 7; wherein such pipes conduct said electrolyte between the components of such system, plurality of valves 8; wherein such valves control the flow of said electrolyte within such device, a single-compartment electrolyzer 9; wherein such electrolyzer has a body 90 made of a corrosion-resistant material to said electrolyte; wherein such body comprises three sections: an inlet section 91; wherein said electrolyte enters such electrolyzer through such inlet, a working section 92; wherein such section comprises an anode 920 and a cathode 921; wherein such anode and cathode are made of a corrosion-resistant material to said electrolyte, and an outlet section 93; wherein the gaseous products of the electrolysis are evolved as bubbles at such section; wherein such bubbles happen due to the presence of the gaseous products and unelectrolyzed electrolyte inside said electrolyzer 9. The device of the present invention also comprises a flash distillation tank 10 for separating gaseous products from unelectrolyzed electrolyte under high pressure; wherein such gaseous products can then be separated using any convenient manner.

The internal design and dimensions of said electrolyzer play an important role in the efficiency of said device, thus the cross-sectional shape of said electrodes 920 and 921 as well as the body of such electrolyzer 9 is considered to be rectangular. Also, the distance that separates said anode 920 and said cathode 921 has to be selected such that to reduce the ohmic drop in the electrolyte which in turn reduces the voltage required for the electrolyzing process, thus, such distance is selected to be 0.6 cm. To control the pressure drop that has a direct effect on the power consumption during electrolysis, the cross-sectional area of said electrolyzer 9 is made to equal 3 cm² because optimum conditions are required to increase the efficiency, and of 82.5 cm length. Said electrolyzer 9 of the present invention is designed with sufficient entrance length in order to achieve fully developed flow, and the working electrode's (i.e. cathode) 921 length is chosen to obtain fully developed mass transfer conditions in presence of fully developed velocity profile. Furthermore, the auxiliary electrode (i.e. anode) 920 was made of area larger than that of said cathode 921 in order to ensure that the limiting current is at said cathode 921 rather than at said anode 920; wherein the length of said cathode 921 is 14 cm and its width is 1.6 cm such that the ratio of the length (L) to the equivalent diameter (dₑ) equals 13.08 (i.e. L/dₑ=13.08) in order to achieve a fully developed mass transfer conditions in the presence of fully developed turbulent flow. Noting that these values were used in building the prototype of the present invention's device at a lab-scale size; wherein such system can be produced at different sizes coping with the required capacity and productivity rate.

The solar light incite at said solar panels 1; wherein such panels convert the energy of such light into electrical energy and conduct it to said car batteries 2 through suitable electrical wires. Said electrolyte flows from said source tank 3 to said container 4 to be stored there in order to be pumped by the effect of said pump 5 through said electrolyzer 9 to become electrolyzed. Said flow meter 6 measures the flow rate of said electrolyte before entering said electrolyzer 9 at said inlet section 91, after the entrance of said electrolyte at such inlet section 91, the electrolysis process starts; during such process, said anode 920 attracts the anions (i.e. negative ions) of said electrolyte; wherein oxidation (losing electrons) takes place at such anode 920 and said cathode 921 attracts the cations (i.e. positive ions) of said electrolyte; wherein reduction (gaining electrons) takes place at such cathode 921. The gaseous products of such electrolysis are evolved as bubbles at the outlet section due to the presence of unelectrolyzed liquid electrolyte. Such products are conducted to said flash distillation tank 10 through said pipes 7 in order to separate gaseous products from liquid products at high pressure. The liquid products can also be separated from unelectrolyzed electrolyte using any convenient technique, such that the unelectrolyzed electrolyte is conducted to said container 4 in order to be re-electrolyzed.

Taking into consideration that, said anode 920 and said cathode 921 are made of graphite and a nickel alloy (Inconel 625) respectively when using sea water as an electrolyte in order to produce a mixture of hydrogen and oxygen gases; wherein such mixture can be separated which enables the utilization of hydrogen as a source of energy using any suitable separation technique, or fused together in a proton exchange membrane fuel cell to get pure water and electricity. The body of said electrolyzer 90 is made of acrylic, taking into consideration that the materials of which said anode 920, cathode 921, and said body 90 itself have to be resistant to corrosion caused by said electrolyte.

To obtain the general equation of oxygen reduction on the cathode, an experiment was performed at three different temperatures, and three Reynolds numbers on different electrodes using 0.1N NaCl solution, and the results are shown in Tables (1-9); wherein Tables (1-3) show the results of reduction of oxygen on Copper electrodes at different temperatures, Tables (4-6) show the results of reduction of oxygen on Stainless steel 316 electrodes at different temperatures, Tables (7-9) show the results of reduction of oxygen on Monel electrodes at different temperatures.

TABLE 1

| Sh | K × 10⁵ (m/s) | i_{L,O2} (μA/cm²) | Re | Temp (° C.) |
|---|---|---|---|---|
| 99.37 | 2.202 | 199.248 | 3242 | 30 |
| 134.3899 | 2.978 | 269.455 | 5349 | |
| 202.6716 | 4.4917 | 406.36 | 7850 | |

TABLE 2

| Sh | K × 10⁵ (m/s) | i_{L,O2} (μA/cm²) | Re | Temp (° C.) |
|---|---|---|---|---|
| 86.9 | 2.4522 | 187.6137 | 2288 | 40 |
| 113.523 | 3.2034 | 245.377 | 3587 | |
| 200.04 | 5.6087 | 429.6131 | 7850 | |

TABLE 3

| Sh | K × 10⁵ (m/s) | i_{L,O2} (μA/cm²) | Re | Temp (° C.) |
|---|---|---|---|---|
| 73.4 | 2.4402 | 164.84 | 2318 | 50 |
| 75.358 | 2.50522 | 169.227 | 2873 | |
| 203.17 | 6.754 | 456.25 | 7850 | |

TABLE 4

| Sh | K × 10⁵ (m/s) | i_{L,O2} (μA/cm²) | Re | Temp (° C.) |
|---|---|---|---|---|
| 108.8159 | 2.411646 | 218.1786 | 3242 | 30 |
| 149.9982 | 3.324352 | 300.75 | 5349 | |
| 202.189 | 4.481037 | 405.3938 | 7850 | |

TABLE 5

| Sh | K × 10⁵ (m/s) | i_{L,O2} (μA/cm²) | Re | Temp (° C.) |
|---|---|---|---|---|
| 87.70237 | 2.4748 | 189.5655 | 2288 | 40 |
| 112.1402 | 3.16449 | 242.3869 | 3587 | |
| 200.04 | 5.6087 | 429.6131 | 7850 | |

TABLE 6

| Sh | K × 10⁵ (m/s) | i_{L,O2} (μA/cm²) | Re | Temp (° C.) |
|---|---|---|---|---|
| 55.10578 | 1.831932 | 123.73 | 2318 | 50 |
| 65.463 | 2.17624 | 147.321 | 2873 | |
| 203.1727 | 6.75425 | 456.25 | 7850 | |

TABLE 7

| Sh | K × 10⁵ (m/s) | i_{L,O2} (μA/cm²) | Re | Temp (° C.) |
|---|---|---|---|---|
| 102.255 | 2.266239 | 123.73 | 2318 | 30 |
| 135.2688 | 2.99791 | 147.321 | 2873 | |
| 202.189 | 4.481037 | 456.25 | 7850 | |

TABLE 8

| Sh | K × 10⁵ (m/s) | i_{L,O2} (μA/cm²) | Re | Temp (° C.) |
|---|---|---|---|---|
| 84.35435 | 2.38037 | 182.3289 | 2288 | 40 |
| 100.629 | 2.839619 | 217.506 | 3587 | |
| 200.04 | 5.6087 | 429.6131 | 7850 | |

TABLE 9

| Sh | K × 10⁵ (m/s) | i_{L,O2} (μA/cm²) | Re | Temp (° C.) |
|---|---|---|---|---|
| 70.12582 | 2.331275 | 157.476 | 2318 | 50 |
| 80.616 | 2.68 | 181.03 | 2873 | |
| 203.1727 | 6.754256 | 456.25 | 7850 | |

After taking Tables (1-9) into account, and after making a least square fit on all given data, the following general equation of oxygen reduction on three electrodes (Copper, Stainless Steel 316, and Monel) was obtained:

Sh=0.033627Re^{0.81}Sc^{0.243} (1)
Correlation Coefficient=09547
   Or

Sh=0.02566Re^{0.793}Sc^{1/3} (2)
Correlation Coefficient=0.9436

### Where:

Sh: Sherwood Number.
Re: Reynold's Number.
i_{L}: Limiting Current.
k: Mass Transfer Coefficient.

The limiting current could be related with the mass transfer coefficient through the following equation:

i_{L}=ZFkC_{b} (3)

### Where:

Z: Charge.
F: faraday's Constant=96500
C_{b}: Concentration of salt in the solution (3-5%)

Any electrochemical reaction does not proceed without applying an external voltage, which is called the voltage required for electrolysis (Vₓ); wherein:

Vₓ=Vₘᵢₙ+V_{tafel}+Vₒₕₘ+V_{conc.} (4)

### Where:

Vₘᵢₙ: The minimum voltage required to achieve electrolysis.
   V_{tafel}: The tafel overpotentials due to the electrolyzing current.
   V_{conc.}=The voltage due to the concentration variation in the solution.

While the invention has been described in details and with reference to specific embodiments thereof, it will be apparent to one skilled in the art that various additions, omissions and modifications can be made without departing from the spirit and scope thereof.

1. A solar-powered single-compartment multi-purpose electrochemical reactor for electrolyzing liquid electrolytes comprising: solar panels, car batteries, source tank, a container, plurality of pipes and valves, means for enhancing the flow rate of such electrolyte through the system, means for measuring the flow rate of such electrolyte, a flash distillation tank, characterized by having a single compartment electrolyzer comprising a body with three sections; an inlet section, a working section; wherein such section includes an anode and a cathode, and an outlet section.

2. The reactor of claim 1, wherein said liquid electrolyte comprises sea water, fresh water, waste water, or any liquid compound or mixture.

3. The reactor of claim 1, wherein the number and the power of said solar panels are selected to suit the capacity and productivity rate of such system.

4. The reactor of claim 1, wherein the number of said car batteries is selected to suit the capacity and the productivity rate of such system.

5. The reactor of claim 1, wherein said source tank and container can be of any shape, and have sizes suitable for the capacity and productivity rate of such system.

6. The reactor of claim 1, wherein said pipes transport said electrolyte and the products of electrolysis between the components of such system.

7. The reactor of claim 1, wherein said valves control the flow of said electrolyte through such system.

8. The reactor of claim 1, wherein said means for enhancing the flow rate of said electrolyte comprises a pump.

9. The reactor of claim 1, wherein said means for measuring the flow rate of said electrolyte comprises a flow meter.

10. The reactor of claim 1, wherein said flash distillation tank separates gaseous products obtained from electrolysis from any other liquids under pressure.

11. The reactor of claim 1, wherein said electrolyte enters said single-compartment electrolyzer through said inlet section.

12. The reactor of claim 1, wherein electrolysis happens in said working section.

13. The reactor of claim 1, wherein the products of electrolysis leaves said single-compartment electrolyzer at said outlet section.

14. The reactor of claim 1, wherein the area of said anode is made larger than that of the cathode.

15. The reactor of claim 1, wherein said single-compartment electrolyzer has a ratio of the length to the equivalent diameter of 13.08.

16. The reactor of claim 1, wherein said single-compartment electrolyzer's body is made of acrylic if said electrolyte is sea water.

17. The reactor of claim 1, wherein said cathode is made of a nickel alloy (Inconel 625) if said electrolyte is sea water.

18. The reactor of claim 1 wherein said anode is made of graphite.

19. The reactor of claim 1, wherein said single-compartment electrolyzer's body, said anode, and said cathode must be fabricated from corrosion-resistant materials to said electrolyte.
